(19) United States
(12) Patent Application Publication
(10) Pub. No.: US 2007/0164280 A1
(43) Pub. Date: Jul. 19, 2007

(54) Thin film transistor, manufacturing method for thin film transistor and manufacturing method for display device

(76) Inventors: Shinji Maekawa, Shizuoka (JP); Osamu Nakamura, Kanagawa (JP); Koji Muranaka, Kumamoto (JP)

Correspondence Address: NIXON PEABODY, LLP, 401 9TH STREET, NW, SUITE 900, WASHINGTON, DC, 20004-2128, US

(21) Appl. No.: 10/569,595

(22) PCT Filed: Aug. 25, 2004
(86) PCT No.: PCT/JP04/12598

§ 371 Date: Nov. 9, 2006

(30) Foreign Application Priority Data
Aug. 28, 2003 (JP) 2003-305364

(51) Int. Cl. H01L 29/04

(52) U.S. Cl. 257/59

(57) ABSTRACT

The present invention provides a thin film transistor that can be manufactured at lower cost and at higher yield by simplifying a manufacturing process, a manufacturing method thereof, and a manufacturing method of a display device using the thin film transistor. According to this invention, a pattern used in a pattering process is formed by using a droplet discharging method. The pattern is formed by selectively discharging a composition comprising an organic resin. By using the pattern, an electrically conductive material, an insulator or semiconductor constituting a semiconductor element, are patterned into a desired shape by a simple process.

### TECHNICAL FIELD

The present invention relates to a thin film transistor utilizing a patterning technique which forms a predetermined pattern by discharging a droplet composition, and a method for manufacturing a display device using the thin film transistor.

### BACKGROUND ART

A thin film transistor (hereinafter, referred to as “TFT”) and an electronic circuit using the thin film transistor is manufactured by laminating various types of thin films of, for example, a semiconductor, an insulator and a conductive material over a substrate and, then, forming a predetermined pattern by appropriately using a photolithography technique. The term “photolithography technique” as used herein is intended to mean a technique which transfers a pattern such as a circuit formed on a surface of a transparent flat plane ordinarily referred to as a “photomask” by using a material which is impervious to light onto a targeted substrate by utilizing light, and the technique has widely been used in a manufacturing process of, for example, a semiconductor integrated circuit.

In a manufacturing process using a conventional photolithography technique, it is necessary to perform a multi-stage process comprising exposing, developing, baking and peeling-off steps for treating even a mask pattern only which is formed by using a photosensitive organic resin material ordinarily referred to as a “photoresist”. Therefore, as the number of steps of the photolithography process is increased more, a manufacturing cost is inevitably increased more. In order to improve such problems as described above, it has been tried to produce the TFT by reducing the number of steps of the photolithography process (for example, refer to Patent Document 1).

However, in the technique described in Patent Document 1, only a part of a plurality of steps of the photolithography process in a TFT manufacturing is replaced by a printing method and no contribution is made to a drastic reduction in the number of steps thereof. Further, in the photolithography technique, an exposing apparatus to be used for transferring the mask pattern transfers a pattern in the range of from several micrometers to 1 micrometer or less by an equivalent projection exposure or a reduction projection exposure and, also, it is theoretically difficult to expose a large area substrate having a side of more than 1 meter all at once from a technical standpoint.

Patent Document 1:

Japanese Patent Laid-Open No. 11-251259

### DISCLOSURE OF INVENTION

An object of the present invention is to provide a technique in which, in a manufacturing process of a TFT, an electronic circuit using the TFT or a display device to be formed by the TFT, the number of steps of the photolithography process is reduced, or the photolithography process itself is eliminated and, accordingly, the manufacturing process is simplified and a manufacturing can be executed on a large area substrate having a side of more than 1 meter at lower cost and, also, at higher yield.

The TFT according to the present invention is a TFT which has a semiconductor film containing a source region, a drain region and a channel forming region over a gate electrode and is characterized in that a protective layer comprising an organic substance is formed at a position at which the channel forming region exists on a surface of the semiconductor film opposite to the gate electrode, that is, the protective layer is formed on the surface of the semiconductor film opposite to another surface of the semiconductor film in contact with an insulating film. In other words, the protective layer is selectively formed over the channel forming region or is formed in contact with at least the channel forming region.

In the TFT according to the present invention, the semiconductor film uses an amorphous semiconductor (hydrogenated amorphous silicon as a representative example) or a crystalline semiconductor (polysilicon as a representative example) as a starting material. Examples of polysilicon include a so-called high-temperature polysilicon which uses as a main material, polycrystalline silicon to be formed through a process temperature of 800° C. or more, a so-called low-temperature polysilicon which uses, as a main material, polycrystalline silicon to be formed at a process temperature of 600° C. or less and crystalline silicon which is crystallized by adding, for example, an element for promoting crystallization.

Further, as other substances, a semi-amorphous semiconductor or such a semiconductor as contains a crystalline phase in a part of a semiconductor film can also be used. The term “semi-amorphous semiconductor” as used herein is intended to mean a semiconductor having an intermediate structure of a amorphous structure and a crystalline structure (including single crystals and poly-crystals) and having a stable third state with respect to free energy, and is a crystalline having a short-distance order and a lattice distortion. Typically, it is a semiconductor film, comprising silicon as a main component, with a lattice distortion, in which Raman spectrum is shifted to a low frequency side from 520 cm⁻¹. Further, at least 1% by atom of hydrogen or a halogen is contained therein as a neutralizing agent of a dangling bond. On this occasion, such semiconductor as described above is called as a semi-amorphous semiconductor (hereinafter, referred to “SAS” in short). The SAS is also called as a so-called microcrystal semiconductor (microcrystalline silicon as a representative example).

The SAS can be obtained by decomposing a silicide gas by means of glow discharge. As for a representative silicide gas, SiH₄ is mentioned. As for other gases than this gas, Si₂H₆, SiH₂Cl₂, SiHCl₃, SiCl₄, SiF₄ and the like can be used. Formation of the SAS can be facilitated by using these silicide gases diluted by hydrogen or a mixture of hydrogen and at least one rare gas selected from among helium, argon, krypton and neon. A dilution ratio of hydrogen against the silicide gas is, for example, preferably in the range of from 5 times to 1000 times in terms of flow volume ratio. Although formation of the SAS by glow discharge decomposition is preferably performed under a reduced pressure, the formation can also be performed under an atmospheric pressure by utilizing an electric discharge. As a representative example, the formation may be performed in the pressure range of from 0.1 Pa to 133 Pa. A power supply frequency for generating the glow discharge is in the range of from 1 MHz to 120 MHz and preferably in the range of from 13 MHz to 60 MHz. A high-frequency power supply may appropriately be set. A temperature for heating the substrate is preferably 300° C. or less and the temperature in the range of from 100° C. to 200° C. is also permissible. As for impurity elements to be incorporated mainly at the time of forming a film, an impurity derived from an atmospheric component such as oxygen, nitrogen or carbon is preferably used in an concentration of 1×10²⁰ cm⁻³ or less and, particularly, a concentration of oxygen is 5×10¹⁹ cm⁻³ or less and preferably 1×10¹⁹ cm⁻³ or less. Further, stability of the SAS can be enhanced by promoting the lattice distortion through allowing a rare gas element such as helium, argon, krypton or neon to be contained, to thereby obtain a favorable SAS.

Still further, it is preferable that the aforementioned semiconductor film is formed by silicon or a semiconductor material comprising silicon as a main component. As for the semiconductor material comprising silicon as a main component, a material in which carbon or germanium is contained in silicon at a rate of 0.1% by atom or more can be utilized.

According to the present invention, a protective layer made of an organic substance comprises at least one polymer substance selected from among polyimide, acryl, benzocyclobutene, polyamide, benzoimidazole and siloxane, as a representative example. Further, other organic substances than those described above may also be usable, so long as they can form an electrically insulating protective layer.

The present invention is characterized in that a TFT or an electronic circuit pattern is formed by a method in which a droplet having a composition comprising an organic substance, an inorganic substance or both of them is selectively discharged on a substrate (hereinafter, referred to also as “droplet discharging method”). The droplet discharging method is a method in which a prepared composition is spouted from a nozzle in accordance with an electric signal to form a minute droplet which is, then, allowed to be attached on a predetermined position and this method is also called as an inkjet method. As for patterns to be formed by the droplet discharging method, an electrically insulating pattern, an electrically conductive pattern or an electrically semi-conductive pattern can be formed by appropriately selecting substances to be contained in the droplet composition.

According to the present invention, by using the droplet discharging method, it becomes unnecessary to perform a conventional photolithography process. Since the droplet discharging method can directly delineate a pattern by using the composition comprising, as a constitutional component, an electrically insulating substance, an electrically conductive substance or an electrically semi-conductive substance, the pattern can selectively be formed in a desired region. In this method, since a photomask is not necessary, this method can easily be applied to a large area substrate and has many advantages such as a high utility efficiency of a raw material. In other words, the droplet discharging method is capable of applying a necessary amount of the droplet composition to a necessary position and is, accordingly, called as the so-called inkjet method.

As for organic substances to be used for a protective layer which is capable of being formed by the droplet discharging method, mentioned is a composition comprising at least a high molecular substance selected from among polyimide, acryl, benzocyclobutene, polyamide, benzoimidazole, polyvinyl alcohol, a material in which a skeleton structure is constructed by allowing silicon (Si) and oxygen (O) to bond with each other and a substituent contains at least hydrogen and a material in which a substituent contains at least one member selected from among fluorine, an alkyl group and an aromatic hydrocarbon (a cyclohexane-type polymer as a representative example). The protective layer can be formed by continuously or intermittently discharging the composition by the droplet discharging method.

Further, as for compositions to be used for forming an electrically conductive pattern of, for example, wiring which is capable of being formed by the droplet discharging method, mentioned is an organic matterial used for the protective layer containing a member selected from silver, gold, copper and indium tin oxide, or an alloy or a compound comprising thereof By forming the electrically conductive pattern by means of continuously or intermittently discharging the composition by the droplet discharging method, the pattern is allowed to function as wiring in which a plurality of elements such as TFT's are connected to one another.

Width or film thickness of the electrically insulating, electrically conductive or electrically semi-conductive pattern can be adjusted in accordance with a size of a nozzle which is an discharging opening for the droplet, a volume of the droplet to be discharged and a correlation of a transfer speed between a nozzle and a substrate on which an discharged composition is put for forming. The volume of the droplet to be discharged can finely be controlled by a pulse frequency to be added to a transducer which controls the discharging volume, a waveform, voltage or the like.

A manufacturing method of a TFT according to the present invention is characterized by following steps of forming a first electric conductor, forming a first insulator and a semiconductor over the first electric conductor in a laminating manner, subjecting the semiconductor to patterning by using a first pattern, forming a second pattern on the patterned semiconductor, forming an impurity region by incorporating an impurity into the semiconductor by making use of the second pattern as a mask, and forming a second electric conductor in contact with the impurity region, and is characterized in that the first and second patterns are each formed by selectively discharging a composition comprising an organic resin and the first and second electric conductors are each formed by selectively discharging a composition comprising an electrically conductive material.

A manufacturing method of a TFT according to the present invention is characterized by following steps of forming a first electric conductor, forming a first pattern on the first electric conductor, subjecting the first electric conductor to patterning by making use of the first pattern, forming a first insulator and a semiconductor over the patterned first electric conductor in a laminating manner, forming a second pattern on the semiconductor, subjecting the semiconductor to pattering by making use of the second pattern, forming a third pattern on the patterned semiconductor, forming an impurity region by incorporating an impurity into the semiconductor by making use of the third pattern as a mask, and forming a second electric conductor on and in contact with the impurity region, and is characterized in that the first to third patterns are each formed by selectively discharging a composition comprising an organic resin and the second electric conductor is formed by selectively discharging a composition comprising an electrically conductive material.

A manufacturing method of a TFT according to the present invention is characterized by following steps of forming a first electric conductor, forming a first pattern on the fist electric conductor, subjecting the first electric conductor to patterning by making use of the first pattern, forming a first insulator and a semiconductor over the patterned first electric conductor in a laminating manner, forming a second pattern on the semiconductor,subjecting the semiconductor to pattering by making use of the second pattern,forming a third pattern on the patterned semiconductor, forming an impurity region by incorporating an impurity into the semiconductor by making use of the third pattern as a mask, and forming a second electric conductor on and in contact with the impurity region, forming a fourth pattern on the second electric conductor, and subjecting the second electric conductor to pattering by making use of the fourth pattern, and is characterized in that the first to fourth patterns are each formed by selectively discharging a composition comprising an organic resin.

According to the above described present invention, by using the protective layer comprising the organic resin material formed on a surface of a side opposite to the gate electrode of the channel forming region as a mask for doping, the source and drain regions are allowed to be formed over the semiconductor film. Namely, the protective layer can simultaneously function as a mask in an ion doping method in which an ionized impurity element, for the purpose of controlling a valence electron, which imparts one conductivity type (p-type or n-type) is accelerated in an electric field and, then, injected in a semiconductor layer, to thereby form a p-type or an n-type impurity region in the semiconductor film.

A manufacturing method for a display device according to the present invention is characterized by following steps of forming a pixel region in which a plurality of first semiconductor elements are arranged over a first substrate, forming a liquid crystal element or a light-emitting element between the first substrate and a second substrate, forming a plurality of driver ICs which each contains a driver circuit in which a plurality of second semiconductor elements are arranged, and each contains an input terminal and an output terminal connected to the driver circuit over a third substrate, separating the plurality of driver ICs into individual driver ICs, and attaching the individual driver ICs around the pixel region formed over the first substrate each as a signal line driver circuit or a scanning line driver circuit, and is further characterized by comprising the steps of forming a pattern which subjects a semiconductor constituting the first semiconductor element to patterning by selectively discharging a composition comprising an organic resin, and forming a channel protective layer of the first semiconductor element by selectively discharging a composition comprising an organic resin.

According to the present invention, an impurity region can be formed in the first semiconductor element by using the channel protective layer as a mask. The impurity region may be formed by subjecting an impurity such as phosphorous (P) which imparts an n-type by an ion doping method, for example, an ion doping treatment or an ion injection method.

Further, according to the present invention, wiring which connects the TFT can be formed by the droplet discharging method. The wiring is formed by selectively discharging a composition comprising an electrically conductive material. More in detail, a composition comprising at least one member selected from among silver, gold, copper and indium tin oxide is selectively discharged. Width or thickness of the wiring can be adjusted by a size of a nozzle which is an discharging opening for the droplet, a volume of the droplet to be discharged and a correlation of a transfer speed between the nozzle and a substrate on which an discharged composition is put for forming.

According to the present invention, by using the droplet discharging method in a manufacturing of the TFT, the electronic circuit using the TFT, the display device using the TFT as a part of a display unit, it becomes unnecessary to perform many steps of, for example, exposing, developing, baking and removing which are necessary in the conventional photolithography process, to thereby simplifying the manufacturing process. Namely, process time is reduced, the number of steps of the manufacturing process is reduced and, accordingly, manufacturing cost can be reduced and, also, manufacturing yield can be enhanced.

Further, in the droplet discharging method, the droplet can be discharged to an arbitrary place by changing a relative position between the nozzle which is an discharging opening of the droplet and the substrate and, since the thickness and width of the pattern to be formed can be adjusted, depending on a nozzle size, a volume of the droplet to be discharged, and a correlation transfer speed between the nozzle and the substrate on which the composition to be discharged is put for forming, a manufacturing can be executed even on a large area substrate having a side of more than 1 meter at lower cost and, also, at higher yield.

### BRIEF DESCRIPTION OF DRAWINGS

FIG. 1 is a diagram showing a structure of this invention.

FIG. 2 is a diagram showing a structure of this invention.

FIG. 3A to 3F are a diagram showing a structure of this invention.

FIG. 4G to 4J are a diagram showing a structure of this invention.

FIG. 5A to 5E are a diagram showing a structure of this invention.

FIG. 6F to 6J are a diagram showing a structure of this invention.

FIG. 7 is a cross-sectional diagram of a display device of this invention.

FIG. 8 is a top diagram of a display device of this invention.

FIG. 9 is a cross-sectional diagram of a display device of this invention.

FIG. 10 is a diagram showing an example of this invention.

FIG. 11 is a diagram showing a top diagram of a pixel of this invention.

FIG. 12A to 12D are an observation image showing a structure of this invention.

FIG. 13A and 13B are a graph showing an electronic property of a TFT of this invention.

FIG. 14 is a diagram showing a top diagram of a pixel of this invention.

FIG. 15A and 15B are a top diagram and a cross-sectional diagram showing a structure of a TFT of this invention.

FIG. 16A and 16B are a graph showing an electronic property of a TFT of this invention.

### BEST MODE FOR CARRYING OUT THE INVENTION

### EMBODIMENT 1

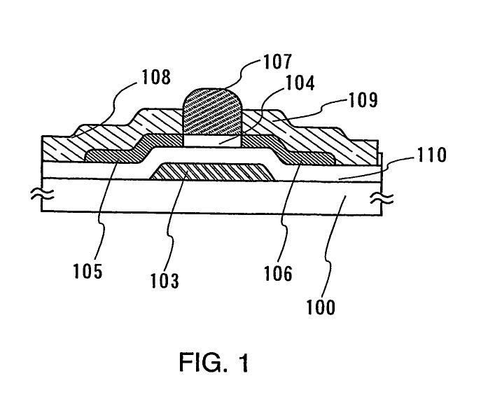

FIG. 1 is a diagram explaining an embodiment of the present invention and shows a reverse stagger-type (bottom gate-type) TFT. In FIG. 1, 100 denotes a substrate; 103 denotes a gate electrode; 110 denotes a gate insulating film; 104 denotes a channel forming region of a semiconductor layer; 105 denotes a source region; 106 denotes a drain region; 107 denotes a channel protective layer; 108 denotes a source electrode; and 109 denotes a drain electrode.

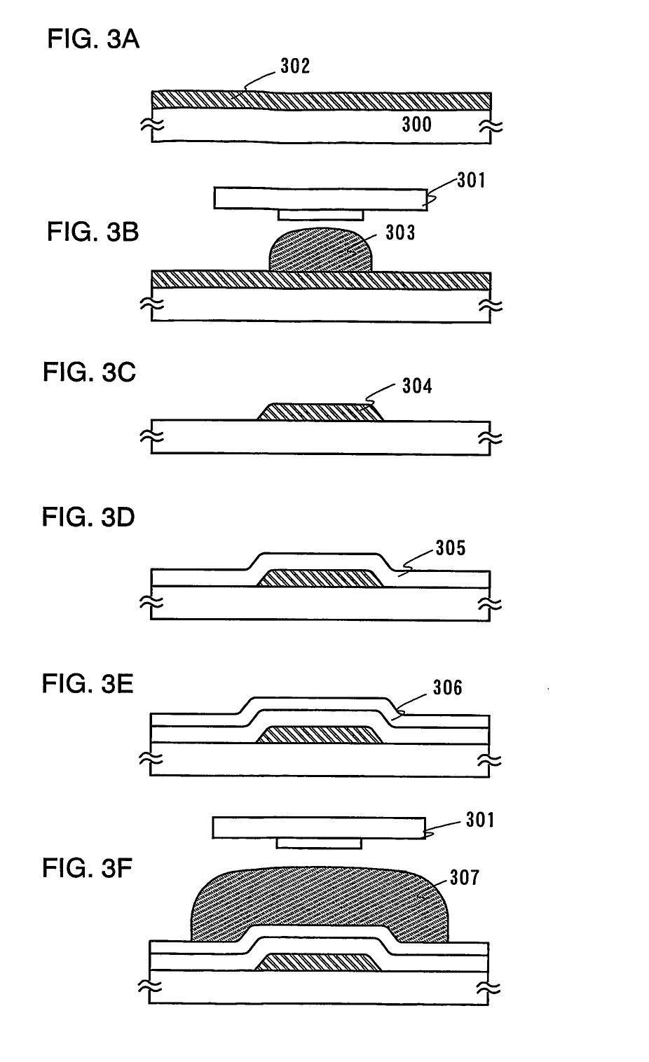

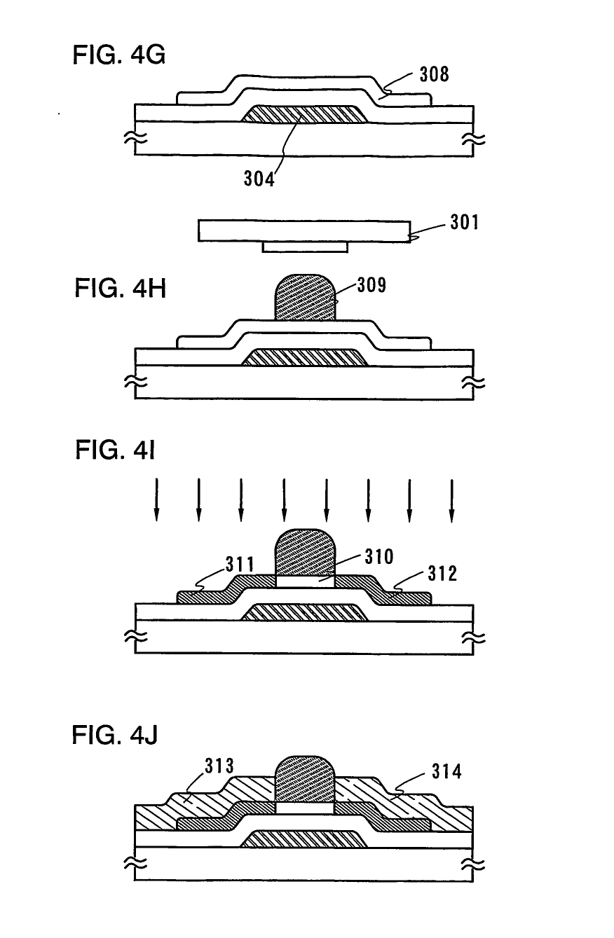

Next, a manufacturing process of the reverse stagger-type TFT according to the present invention is explained with reference to FIGS. 3 and 4.

As for a substrate 300 having an insulating surface, a substrate formed by an insulating substance such as glass, quartz, plastic or alumina, a substrate in which an insulating film of, for example, silicon oxide or silicon nitride is formed on a surface of, for example, a metal such as stainless steel or a semiconductor substrate can be utilized. Further, it is preferable that an insulating film, such as that of silicon oxide, silicon nitride or silicon oxide nitride, which can prevent proliferation of an impurity or the like from the side of the substrate is formed on a surface of the substrate of, for example, plastic or alumina.

On the substrate 300, formed is an electrically conductive film 302. The electrically conductive film 302 may be formed by using an element selected from among Ta, W, Ti, Mo, Al and Cu, or an alloy material or a compound material comprising aforementioned elements as a main component. Further, a constitution thereof is not limited to a mono-layer structure, and a multi-layer structure such as a double-layer structure, a three-layer structure or the like may be permissible (see FIG. 3A).

When the electrically conductive film 302 is subjected to patterning, a droplet discharging method is applied. The droplet discharging method selectively discharges a composition, to thereby form a pattern. By using the droplet discharging method, the patterning of the electrically conductive layer 302 can be performed while using a mask pattern 303 in which delineation is performed only in a desired region. The mask pattern 303 can be formed by selectively discharging a composition comprising an organic substance such as acryl, benzocyclobutene, polyamide, polyimide, benzoimidazole or polyvinyl alcohol from a nozzle 301 onto the electrically conductive film 302 by using the droplet discharging method (see FIG. 3B).

Further, a composition comprising a photosensitive agent is permissible such as a positive resist comprising novolac resin and a naphthoquinone diazide compound as a photosensitive agent, which is dissolved or dispersed in a known solvent; and a negative resist that comprises base resin and diphenylsilanediol, an acid generating agent and the like are dissolved or dispersed in a known solvent may be used. Further, a material containing a skeleton structure which is constructed by allowing silicon (Si) and oxygen (O) to bond with each other and at least hydrogen in a substituent or a material containing at least one member selected from among fluorine, an alkyl group and an aromatic hydrocarbon in a substituent (siloxane-type polymer as a representative example) may be used.

It is preferable that the mask pattern 303 to be formed by the droplet discharging method is baked and hardened to be in a state in which the electrically conductive film 302 can be subjected to an etching treatment. Then, by subjecting the electrically conductive film 302 to the etching treatment by making use of the mask pattern 303, predetermined electrode and wiring pattern are formed. Namely, in such steps as described above, a gate electrode 304 is formed. The mask pattern 303 is removed after such pattering is performed (see FIG. 3C).

Further, the gate electrode 304 can also be formed by the droplet discharging method. It can be formed by selectively discharging a composition comprising an electrically conductive material on the substrate 300. In this case, a diameter of the nozzle for use in a droplet discharging device is set in the range of from 0.1 μm to 50 μm (favorably from 0.6 μm to 26 μm) and a volume of the composition to be discharged from the nozzle is set in the range of from 0.00001 pl to 50 pl (favorably from 0.0001 pl to 10 pl). The volume of the composition to be discharged increases in proportion with a size of the diameter of the nozzle. Further, it is preferable that a distance between a subject to be treated and the discharging opening of the nozzle is as small as possible in order to drop the droplet on a desired position. The distance is favorably set in the range of from about 0.1 mm to about 2 mm.

As for the composition to be discharged from the discharging opening, a composition in which an electric conductor is dissolved or dispersed in a solvent is used. As for such electric conductors, a fine particle or a dispersant nano-particle of a metal such as Ag, Au, Cu, Ni, Pt, Pd, Ir, Rh, W or Al, a sulfide of a metal such as Cd or Zn, an oxide of a metal such as Fe, Ti, Si, Ge, Zr or Ba, or silver halide may be used. In other cases, an indium tin oxide (hereinafter, referred to also as “ITO” in short), an organic indium, an organic tin, ZnO (zinc oxide), TiN (titanium nitride) and the like can be used. Further, as for compositions to be discharged from the discharging opening, it is preferable that, taking a specific resistance value into consideration, any one material selected from among gold, silver and copper is dissolved or dispersed in a solvent and, then, the resultant solution or dispersion thereof is used. It is more preferable that silver or copper having a low resistance value may be used. When such copper is used, as a measure for an impurity, a barrier film may simultaneously be provided. As for such solvents, esters such as butyl acetate and ethyl acetate; alcohols such as isopropyl alcohol and ethyl alcohol; and organic solvents such as methyl ethyl ketone and acetone may be used.

As for the barrier film in which copper is used for wiring, an insulating or electrically conductive substance containing nitrogen such as silicon nitride, silicon oxide nitride, aluminum nitride, titanium nitride or tantalum nitride may be used. Such substances may be put for forming by the droplet discharging method.

Further, a viscosity of the composition to be used by the droplet discharging method is favorably 300 cp or less. This is because drying of the composition is prevented and the composition is allowed to be smoothly discharged from the discharging opening. Still further, the viscosity, surface tension and the like of the composition may appropriately be adjusted depending on types of solvents to be used or applications. For example, the viscosity of the composition in which ITO, the organic indium or the organic tin is dissolved or dispersed in a solvent is in the range of from 5 mPa·S to 50 mPa·S, the viscosity of the composition in which silver is dissolved or dispersed in a solvent is in the range of from 5 mPa·S to 20 mPa·S, and the viscosity of the composition in which gold is dissolved or dispersed in a solvent is in the range of from 10 mPa·S to 20 mPa·S.

Although depending on a diameter of each nozzle, a pattern in a desired shape and the like, in order to prevent clogging of the nozzle or to produce a highly fine pattern, a diameter of a particle of an electric conductor is preferably as small as possible. Preferably, it is 0.1 μm or less. The composition is formed by a known method such as an electrolytic deposition method, an atomizing method or a wet reduction method and a particle size thereof is ordinarily in the range of from about 0.5 μm to about 10 μm. However, when it is formed by an evaporation-in-gas method, a nano-molecule protected by a dispersant is as fine as about 7 nm and, when a surface of each particle of such nano-particles is covered by a covering agent, they do not agglomerate with one another, are stably dispersed at room temperature and behave in an approximately same manner as a liquid. Therefore it is preferable to use the covering agent.

Next, an insulating layer 305 is formed (see FIG. 3D). The insulating layer 305 is preferably formed by silicone nitride, silicon oxide or a silicon-containing insulating film by means of a thin film forming method such as a plasma CVD method or a sputtering method.

On the thus-formed insulating layer 305, a semiconductor layer 306 is formed (see FIG. 3E). The semiconductor layer 306 is formed by using an amorphous semiconductor, a crystalline semiconductor or a semi-amorphous semiconductor. In any case, a semiconductor film of silicon or containing silicon as a main component is formed.

On the semiconductor layer 306, a mask pattern 307 is formed in a same manner as in the mask pattern 303 by the droplet discharging method (see FIG. 3F). The mask pattern 307 is preferably formed by using a thermally resistant polymer. In this case, it is preferable to use a polymer which has an aromatic ring or a heterocycle in a main chain thereof, has least of an aliphatic portion and contains a heteroatomic group of high polarity. As for representative examples of such polymers, mentioned are polyimide and polybenzoimidazole. When polyimide is used, a composition comprising polyimide is discharged from the nozzle 301 onto the semiconductor layer 306 and baked at 200° C. for 30 minutes, to thereby form the pattern 307 . Thereafter, by using the pattern 307 , the semiconductor layer 306 is subjected to patterning, to thereby form a semiconductor layer 308 (see FIG. 4 G). The mask pattern 307 is also removed in a same manner as in the mask pattern 303 after such patterning is performed.

Next, a protective layer 309 is formed in contact with the semiconductor layer 308 in a position in which it overlaps the gate electrode 304. The protective layer 309 is formed on the semiconductor layer 308 such that it is directly delineated by the droplet discharging method. In a droplet composition, any compound capable of forming an electrically insulating film such as acryl, benzocyclobutene, polyamide, polyimide, benzoimidazole or polyvinyl alcohol is selected. It is favorable to form the protective layer comprising polyimide. By making use of the protective layer 309, an impurity element is doped in the semiconductor layer 308 and, for this account, thickness of the protective layer 309 is set to be 1 μm or more and preferably 5 μm or more (see FIG. 4H).

By performing the doping treatment, an impurity region of one conductivity type (p-type or n-type) is formed in a region of the semiconductor layer 308 which is not covered by the protective layer 309. As for impurity elements, boron (B) which imparts an p-type, or arsenic (As) or phosphorous (P) which imparts a n-type may be used. The doping treatment can be performed by an ion doping method or an ion injection method. By performing this doping treatment, a channel forming region 310, an impurity region 311 which is a source region and another impurity region 312 which is a drain region are formed in the semiconductor layer 308. The impurity region 311 and the impurity region 312 are added with one conductivity type (p-type or n-type) impurity (see FIG. 4I).

Further, the protective layer 309 is allowed to remain without being removed and used as a channel protective film. In this case, without impairing reliability of the TFT, the manufacturing process can be simplified. Thereafter, a source electrode 313 and a drain electrode 314 are formed on the impurity region 311 which is the source region and another impurity region 312 which is the drain region by the droplet discharging method (see FIG. 4J). As for the electric conductor, such electric conductor as indicated in the aforementioned gate electrode may be used and, as an example, a composition comprising Ag is selectively discharged and baked by being subjected to a thermal treatment, to thereby forming an electrode having a thickness in the range of from 600 nm to 800 nm.

As is described above, by forming the mask pattern by the droplet discharging method, steps of, for example, applying a resist, baking the resist, exposing, developing and baking after such development can be omitted. As a result, a substantial reduction of cost can be aimed due to simplification of the process.

Further, the pattern can be formed in an arbitrary place and, since width or thickness of the pattern to be formed can be adjusted, a manufacturing can be executed on a large area substrate having a side of more than 1 meter at lower cost and, also, at higher yield.

### EMBODIMENT 2

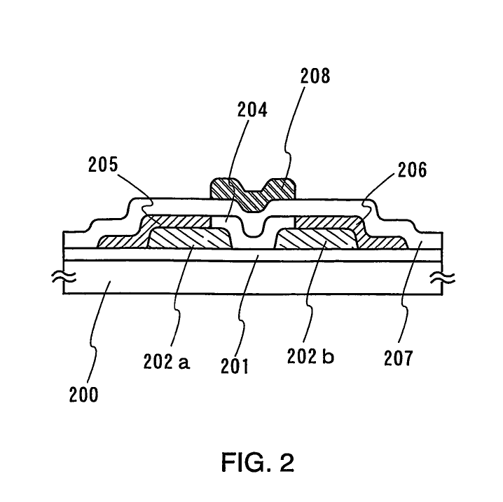

FIG. 2 is a diagram explaining a positive stagger-type (top gate-type) TFT according to the present invention. In FIG. 2, 200 denotes a substrate; 201 denotes a base film; 202a denotes a source electrode; 202b denotes a drain electrode; 204 denotes a channel forming region of a semiconductor layer; 205 denotes a source region; 206 denotes a drain region; 207 denotes a gate insulating film; and 208 denotes a gate electrode.

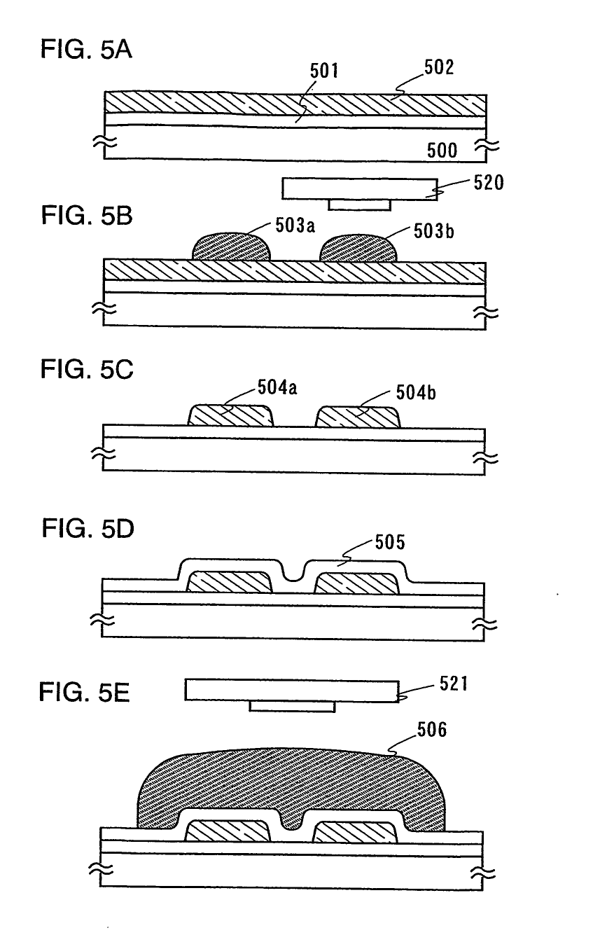

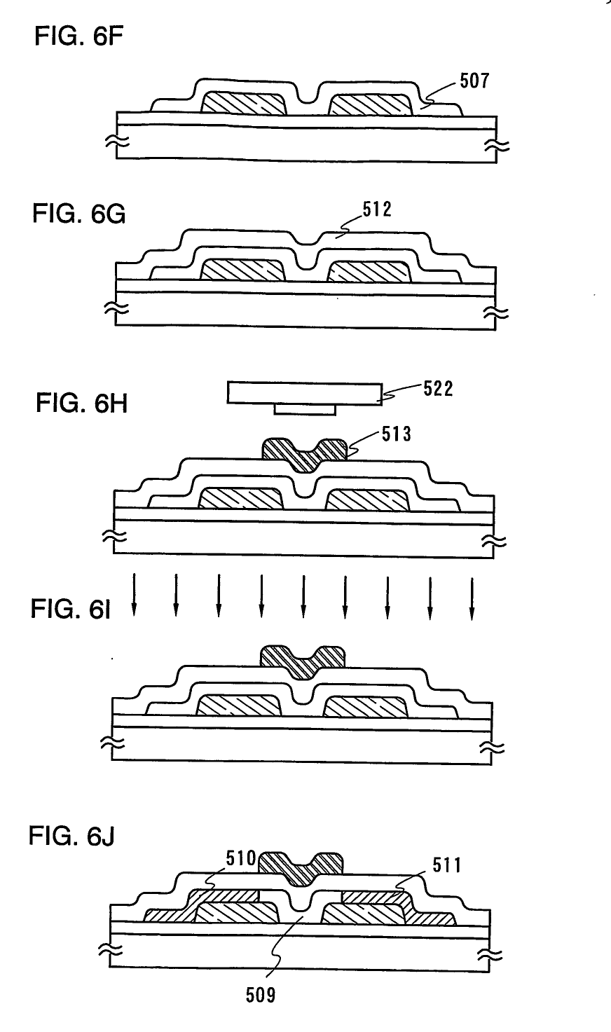

Next, a manufacturing process of the positive stagger-type TFT is explained with reference to FIGS. 5 and 6.

A base film 501 is formed on a substrate 500 having an insulating surface. As for the substrate 500, a substrate formed by an insulating substance such as glass, quartz or alumina, a substrate in which an insulating film of, for example, silicon oxide or silicon nitride is formed on a surface of, for example, a metal such as stainless steel or a semiconductor substrate can be utilized. Further, a flexible or non-flexible plastic substrate having thermal resistance enough to withstand a maximum treating temperature in a manufacturing process such as a baking temperature of a pattern formed by a droplet discharging method or a thermal treating temperature in an activation treatment of one conductivity type (p-type or n-type) impurity added in source and drain regions of the semiconductor layer can be used. Further, as for the base film, a silicon oxynitride film, a silicon nitride oxide film or the like may be used and, in this case, a mono-layer film or a film having a structure in which two layers or more are laminated with one another may be used.

An electrically conductive film 502 is formed on the base film 501. The electrically conductive film may be formed by an alloy material or a compound material comprising at least one element selected from among Ta, W, Ti, Mo, Al and Cu. Further, the electrically conductive film 502 is not limited to a mono-layer structure, and other structures, for example, a structure in which a plurality of layers, such as two layers or three layers, are laminated with one another, are permissible (see FIG. 5A).

Next, in order to subjecting the electrically conductive film 502 to patterning, mask patterns 503a and 503b are formed by using the droplet discharging method. The mask patterns 503a and 503b are directly formed such that it is delineated by discharging a composition containing an organic resin from a nozzle 520 onto the electrically conductive film 502 (see FIG. 5B).

In these mask patterns 503a and 503b, an organic resin of, for example, acryl, benzocyclobutene, polyamide or polyimide may be used. Further, a material containing a skeleton structure which is constructed by allowing silicon (Si) and oxygen (O) to bond with each other and at least hydrogen in a substituent or a material containing at least one member selected from among fluorine, an alkyl group and an aromatic hydrocarbon in a substituent (siloxane-type polymer as a representative example) may be used. In the present Embodiment, polyimide is used. Further, a composition comprising a photosensitive agent is permissible, in this case, a positive resist comprising novolac resin and a naphthoquinone diazide compound as a photosensitive agent, which is dissolved or dispersed in a known solvent; and a negative resist that comprises base resin and diphenylsilanediol, an acid generating agent and the like are dissolved or dispersed in a known solvent may be used.

By using the mask patterns 503a and 503b, the electrically conductive film 502 is subjected to etching, to thereby form a source electrode 504a and a drain electrode 504b (see FIG. 5C). As for gases for etching, a chlorine-type gas represented by Cl₂, BCl₃, SiC₄ or CCl₄, a fluorine-type gas represented by CF₄, SF₆ or NF₃, or O₂ may appropriately be used. The mask patterns 503a and 503b are removed after such etching is performed.

Further, the source electrode 504a and the drain electrode 504b can be formed by using the droplet discharging method. In this case, they can be formed by selectively discharging a composition comprising an electrically conductive material onto the base film 501.

A diameter of a nozzle to be used in a droplet discharging device is set to be in the range of from 0.1 μm to 50 μm (favorably from 0.6 μm to 26 μm) and a volume of the composition to be discharged from the nozzle is set to be in the range of from 0.00001 pl to 50 pl (favorably from 0.0001 pl to 10 pl). The volume of the composition to be discharged increases in proportion with a size of the diameter of the nozzle. Further, it is preferable that a distance between a subject to be treated and the discharging opening of the nozzle is as small as possible in order to drop the droplet on a desired position. The distance is favorably set to be in the range of from about 0.1 mm to about 2 mm. As for the composition to be discharged from the discharging opening, a composition in which an electric conductor is dissolved or dispersed in a solvent in a same manner as in Embodiment 1 is used.

A semiconductor layer 505 is formed on the source electrode 504a and drain electrode 504b (see FIG. 5D). The semiconductor layer 505 is formed by using an amorphous semiconductor, a crystalline semiconductor or a semi-amorphous semiconductor. In any case, it is formed by using silicon or a semiconductor film containing silicon as a main component, for example, silicon-germanium (SiGe).

A mask pattern 506 is formed on the semiconductor layer 505 by the droplet discharging method. The mask pattern 506 is directly formed such that it is delineated by discharging the composition comprising an organic resin from a nozzle 521 onto the semiconductor layer 505 (see FIG. 5E). The semiconductor layer 505 is subjected to patterning by using the mask pattern 506, to thereby form a semiconductor layer 507 (see FIG. 6F).

Next, an insulating layer 512 is formed (see FIG. 6G). The insulating layer 512 is formed by an insulating film comprising silicon by using the plasma CVD method or a sputtering method. The insulating layer 512 is formed on the semiconductor layer 507 and functions as a gate insulating film of the TFT.

A gate electrode 513 is formed on the insulating layer 512 by the droplet discharging method. The gate electrode 513 is directly formed such that it is delineated by discharging a composition comprising an electrically conductive material from a nozzle 522 onto the insulating layer 512 (see FIG. 6H). As for the electrically conductive material, the material as indicated in the aforementioned gate electrode can be used.

Next, one conductivity type (p-type or n-type) impurity region is formed by doping an impurity element in a semiconductor layer 507 while using the gate electrode 513 as a mask (see FIG. 6I).

By performing doping by using the gate electrode 513 as a mask, a channel forming region 509, and a source region 510 and a drain region 511 which are each an n-type impurity region are formed to complete the positive stagger-type TFT according to the present invention (see FIG. 6J). After the doping is performed, activation may be performed by a thermal treatment.

Although not shown, wiring connected to the gate electrode, and other wirings connected to the source electrode and the drain electrode can be manufactured by making use of the droplet discharging method. Namely, a mask pattern is formed by the droplet discharging method and, then, etching processing may be performed, or the wiring may be formed such that it is directly delineated by using an electrically conductive composition. When the wiring is manufactured by the droplet discharging method, the discharging opening is changed to another one depending on width of the wiring, to thereby adjust a volume of the composition to be discharged. For example, a gate line and the gate electrode are each formed in a desired shape such that the gate line has a wider pattern while the gate electrode has a finer pattern.

As is described above, by forming the mask pattern by the droplet discharging method, steps of applying the resist, baking the resist, exposing, developing, baking after such development and the like can be omitted. As a result, a substantial reduction of cost can be aimed due to simplification of the process.

Further, since the pattern can be formed in an arbitrary place and thickness and width of the pattern to be formed can be adjusted, a manufacturing can be performed on a large area substrate having a side of more than 1 meter at lower cost and, also, at higher yield.

### EXAMPLES

### Example 1

In the present Example, a manufacturing process of a reverse stagger-type TFT described in Embodiment 1 is explained with reference to FIGS. 3 and 4.

A W film having a thickness of 100 nm is formed as an electrically conductive film 302 on a substrate 300 by using a sputtering method (see FIG. 3A).

Next, in order to subjecting the electrically conductive film 302 to patterning, a mask pattern 303 is formed by a droplet discharging method. The mask pattern 303 is formed by selectively discharging a composition comprising polyimide on an electrically conductive film 302 (see FIG. 3B). The composition comprising polyimide discharged on the electrically conductive film 302 is hardened by being baked at 200° C. for 30 minutes. In the present Example, the mask pattern is formed in a film thickness of 600 nm.

By using the mask pattern 303, the electrically conductive film 302 is subjected to dry etching while using a mixed gas of Cl₂, SF₆ and O₂ as an etching gas, to thereby form a gate electrode 304 (see FIG. 3C).

Next, a silicon oxynitride film having a thickness of 110 nm is formed as an insulating layer 305 by the plasma CVD method while using SiH₄, NH₃ and N₂O as reactive gases (see FIG. 3D). The silicon oxynitride film is allowed to function as a gate insulating film in the reverse stagger-type TFT according to the present Example. Further, a silicon nitride film may be formed such film forming conditions as substrate temperature: from 60° C. to 85° C., film-forming gas: silane (SiH₄), nitrogen (N₂), and Ar, gas flow volume: silane (SiH₄): 2 SCCM, nitrogen (N₂): 300 SCCM, and Ar: 500 SCCM.

On the insulating layer 305, a hydrogenated amorphous silicon layer having a thickness of 50 nm is formed as a semiconductor layer 306 by the plasma CVD method (see FIG. 3E).

On the semiconductor layer 306, a composition comprising polyimide is discharged by the droplet discharging method to delineate a predetermined pattern and, then, the thus-delineated pattern is baked by being subjected to a thermal treatment at 200° C. for 30 minutes. As a result, a mask pattern 307 is formed (see FIG. 3F).

The semiconductor layer 306 is subjected to dry etching by a mixed gas of CF₄ and O₂, to thereby form a semiconductor layer 308 which is a hydrogenated amorphous silicon layer (see FIG. 4G). Thereafter, the mask pattern 307 is removed by using a peeling liquid comprising 2-aminoethanol HOC₂H₄NH₂ (30 wt %) and a glycol ether R-(OCH₂)₂OH (70 wt %).

Next, on the semiconductor layer 308, a protective layer (channel protective film) 309 comprising polyimide is formed by the droplet discharging method. Thereafter, by using the protective layer 309 as a mask, an impurity regions 311 and 312 are formed while doping phosphorous in the semiconductor layer 308 (see FIGS. 4H and 4I). These impurity regions 311 and 312 form a source and drain regions, respectively, in the reverse stagger-type TFT according to the present Example.

On the impurity regions 311 and 312 which form source and drain regions, respectively, electrodes 313 and 314 are formed such that these electrodes are connected to the impurity regions 311 and 312, respectively. A composition comprising Ag is selectively discharged to form predetermined patterns in a thickness in the range of from 600 nm to 800 nm such that they are electrically connected to the impurity regions 311 and 312, respectively and, then, baked by being subjected to a thermal treatment at 230° C. for 1 hour to form the electrodes 313 and 314. In such manner as described above, the reverse stagger-type TFT is completed.

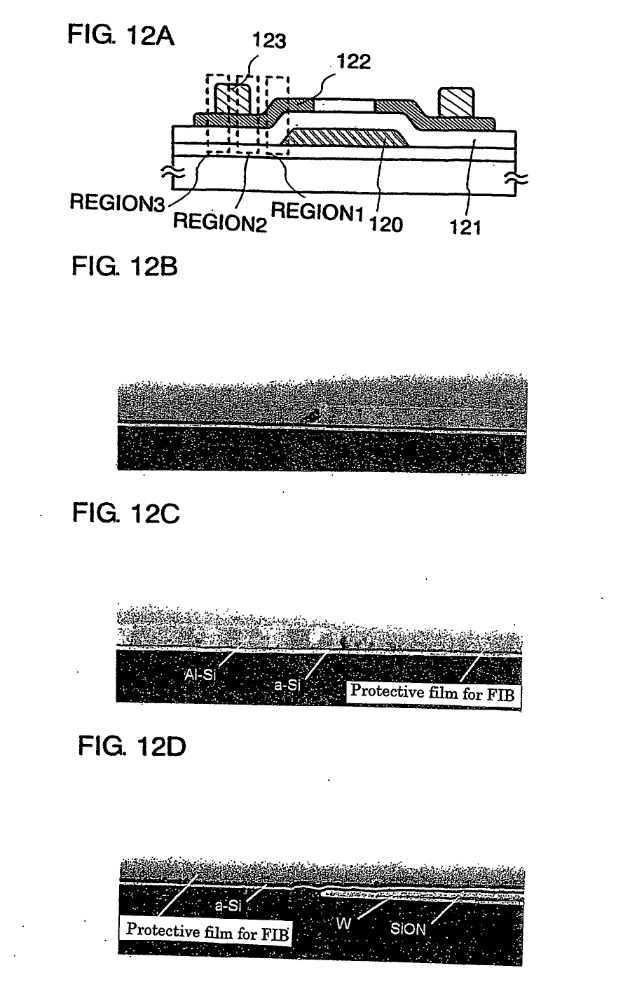

FIG. 12 shows a cross-sectional SEM image of the TFT manufactured in the present Example. This TFT was processed by a focused ion beam processing observation apparatus (FIB). In FIG. 12, 120 denotes a gate electrode comprising a W film; 121 denotes a gate insulating film comprising an SiON film; 122 denotes an amorphous semiconductor comprising a silicon film and also denotes an impurity region, and 123 denotes an electrode comprising an Al-Si alloy. A region 1 of the TFT, a region 2 thereof and a region 3 thereof as indicated in FIG. 12A are shown in FIGS. 12B, 12C and 12D, respectively.

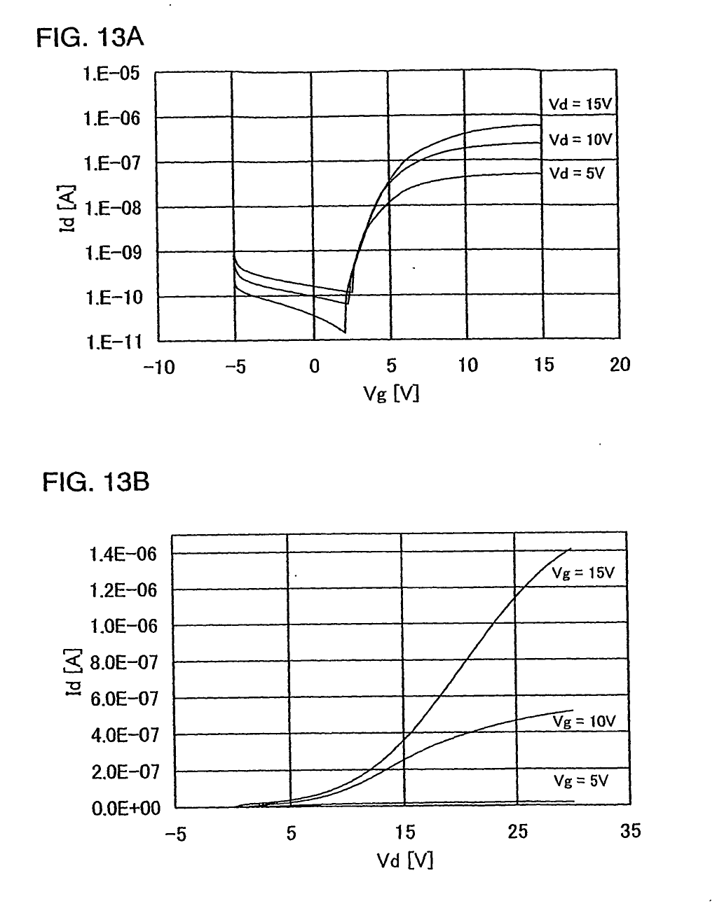

Further, electric characteristics of the reverse stagger-type TFT according to the present invention are shown in FIGS. 13A and 13B. FIG. 13A shows gate voltage (Vg)-drain current (Id) characteristics at the time drain voltages (Vd) are 5V, 10V and 15V. FIG. 13B shows drain voltage (Vd)-drain current (Id) characteristics at the time gate voltages (Vg) are 5V, 10V and 15V. An electric field effect mobility thereof (μ) is 0.313 cm²/Vsec. and a threshold voltage thereof is 3.10 V.

### Example 2

In the present Example, a manufacturing process of a positive stagger-type TFT described in Embodiment 2 is explained with reference to FIGS. 5 and 6.

Firstly, a silicon oxynitride film having a thickness of 100 nm is formed as a base film 501 on a substrate 500 which is a glass substrate. According to the present Example, the film is formed by the plasma CVD method while using SiH₄ and N₂O as reactive gasses.

On the base film 501, a W film having a thickness of 100 nm is formed as an electrically conductive film 502 by the sputtering method (see FIG. 5A).

In patterning of the electrically conductive film 502, mask patterns 503a and 503b are formed by the droplet discharging method such that they are directly delineated by discharging a composition comprising polyvinyl alcohol (see FIG. 5B).

By making use of these mask patterns 503a and 503b, the electrically conductive film 502 is subjected to dry etching while using a mixed gas of Cl₂, SF₆ and O₂. The mask patterns 503a and 503b can be removed with water after the patterning is performed. In such manner as described above, a source electrode 504a and a drain electrode 504b are formed (see FIG. 5C).

Next, on the source electrode 504a and drain electrode 504b, a hydrogenated amorphous silicon film having a thickness of 50 nm is formed as a semiconductor layer 505 by the plasma CVD method (see FIG. 5D).

On the semiconductor layer 505, a mask pattern 506 is formed by the droplet discharging method. The mask pattern 506 is formed such that a composition comprising polyimide is directly discharged on the semiconductor layer 505 and, then, hardened by being subjected to a thermal treatment at 200° C. for 30 minutes using a clean oven (see FIG. 5E). The semiconductor layer 505 is subjected to etching by a mixed gas of CF₄ and O₂, to thereby form a hydrogenated amorphous silicon layer as a semiconductor layer 507 (see FIG. 6F).

Subsequently, a silicon nitride film having a thickness of 110 nm is formed as an insulating layer 512 by the plasma CVD method (see FIG. 6G). Further, the silicon nitride film is formed by the plasma CVD method under such film forming conditions as substrate temperature: from 60° C. to 85° C., film-forming gas: silane (SiH₄); nitrogen (N₂); and Ar, and gas flow volume ratio: SiH₄:N₂:Ar=2:300:500.

The silicon nitride film is allowed to function as a gate insulating film in the positive stagger-type TFT according to the present Example.

On the insulating layer 512, a gate electrode 513 is formed by the droplet discharging method such that a composition comprising Ag is selectively discharged by the droplet discharging method and, then, subjected to a thermal treatment at 230° C. for 1 hour (see FIG. 6H).

Next, phosphine (PH₃) which is an n-type impurity element is subjected to glow discharge decomposition to generate an ion species thereof and, then, the ion species is accelerated in an electric filed and, thereafter, injected in a semiconductor layer 507 by making use of the gate electrode 513 as a mask (see FIG. 6I).

By performing such steps as described above, an n-type impurity region in which phosphorous is added is formed in the semiconductor layer 507. Namely, a channel forming region 509 is formed in a region that is overlapped with the gate electrode 513 of the semiconductor layer 507, and a source region 510 and a drain region 511 which are each an n-type impurity region are formed (see FIG. 6J). In such manner as described above, the positive stagger-type TFT is completed.

### Example 3

In the present Example, an example of a display panel provided with a reverse stagger-type TFT capable of being manufactured in a same process as in Example 1 is explained.

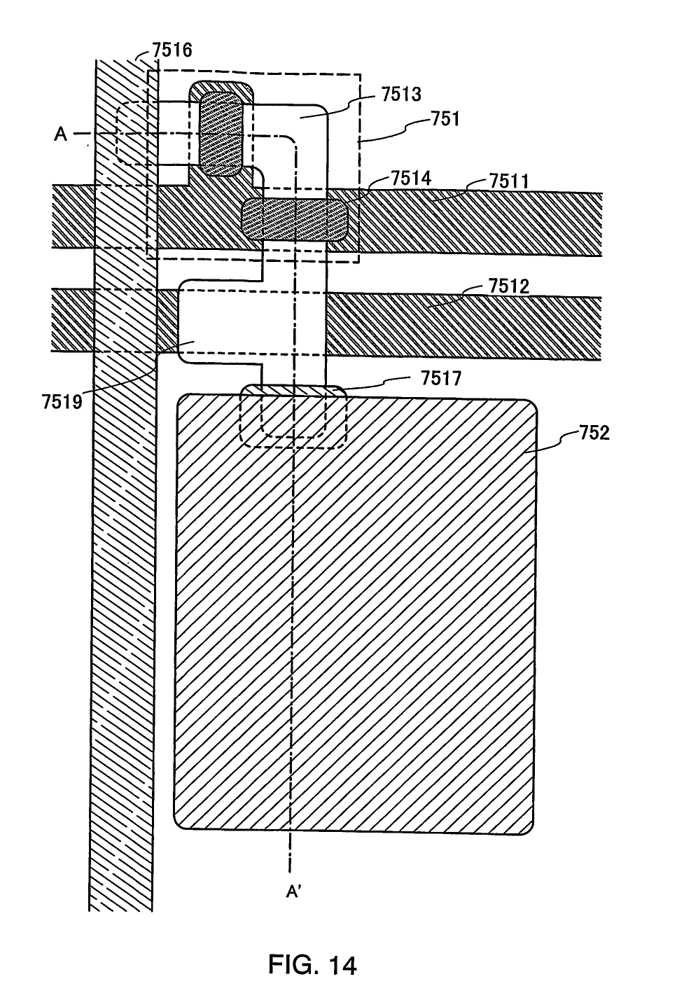

FIG. 14 shows a top view of pixels in a liquid crystal display panel to be manufactured by using a reverse stagger-type TFT 751. The reverse stagger-type TFT 751 has a multi-gate structure. A semiconductor layer 7513 such as a hydrogenated amorphous silicon film is formed thereover. In a region in which a gate electrode 7511 and the semiconductor layer 7513 are lapped with each other, a protective layer 7514 formed directly by a droplet discharging method is provided. A source electrode 7516 is formed such that it crosses a gate electrode 7511. When a pixel electrode 752 is a transmission-type liquid crystal display panel, it is formed by using a transparent electrically conductive material such as indium tin oxide (ITO), zinc oxide (ZnO) or titanium nitride (TiN) such that it is in contact with the semiconductor layer 7513 either via a drain electrode 7517 or directly. When the pixel electrode 752 is a reflection-type liquid crystal display panel, it can also be formed simultaneously with the drain electrode 7517 by using either aluminum or an electrically conductive material comprising aluminum as a main component. A holding capacitance 7519 is formed by a capacitance line 7512 which is formed in a same process as in the semiconductor layer 7513 and the gate electrode 7511.

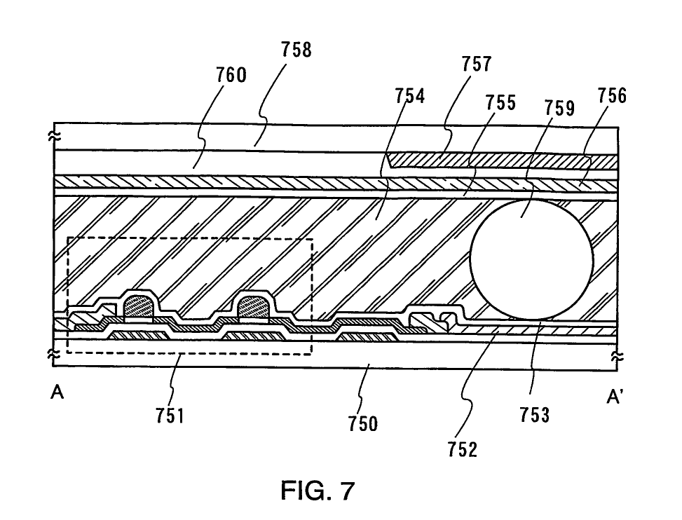

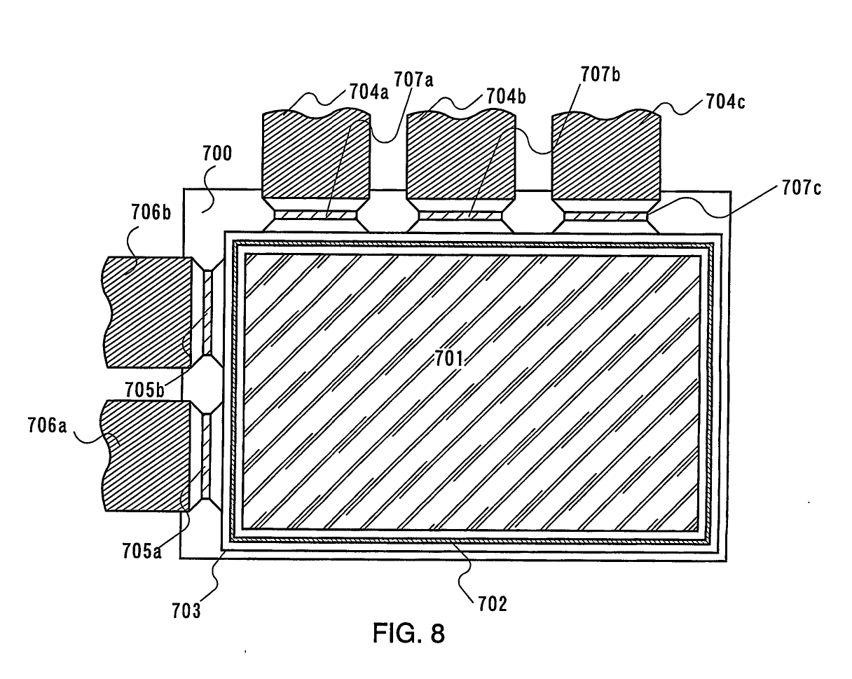

FIG. 7 shows a cross-sectional diagram corresponding to FIG. 14 and, shows a state in which liquid crystal 754 is sealed via spacer 759 between one substrate 750 over which a reverse stagger-type TFT 751 is formed and an opposing substrate 758 over which an opposing electrode 756 and a coloring layer 757 are formed via an insulating layer 760. An orientation film 753 is formed on the pixel electrode 752 which is connected to the reverse stagger-type TFT 751.

On the opposing substrate 758, the coloring layer 757 is formed and, also, the insulating layer 760 is formed. The insulating layer 760 functions as both a protective layer and a flattening layer. The opposing electrode 756 is formed by a transparent electrically conductive material and the orientation film 755 is formed thereon. Further, it is possible to form the opposing electrode 756 or the coloring layer 757 by using the droplet discharging method and, in this case, the number of steps of the manufacturing process can be reduced.

According to the present Example, the transmission-type display panel using a liquid crystal element is manufactured, but the present invention is not limited thereto and is applicable also to a light-emitting device using a light-emitting element. Further, in the present Example, described is an example in which the liquid crystal display panel is constituted by the reverse stagger-type TFT as described in Example 1; however, the panel can also be similarly manufactured by using the positive stagger-type TFT as described in Example 2.

### Example 4

In the present Example, another example of the display panel provided with the reverse stagger-type TFT capable of being manufactured in a same process as in Example 1 is explained.

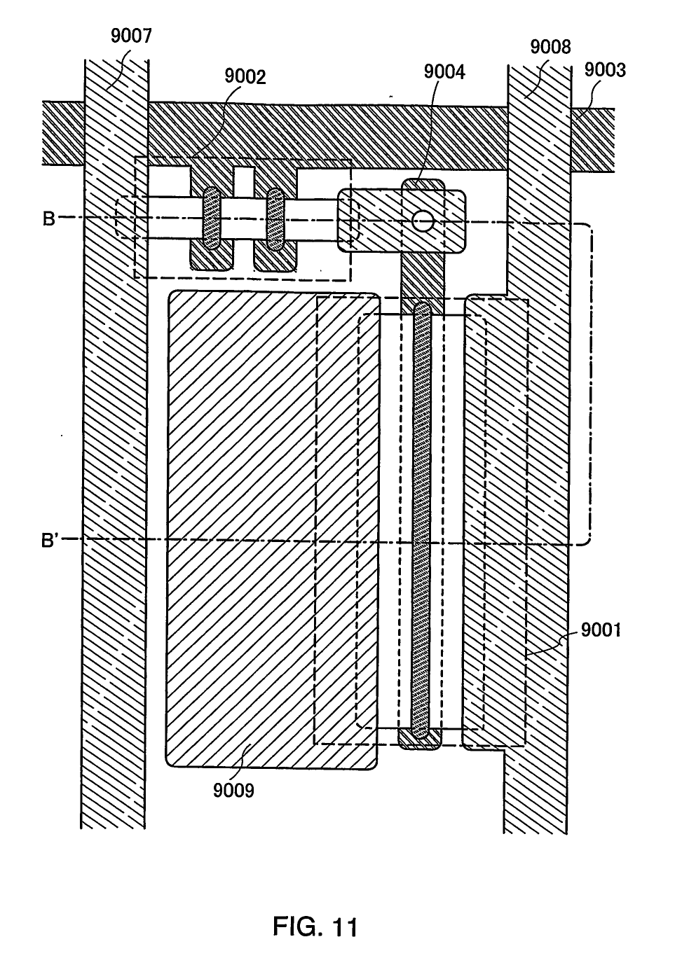

FIG. 11 shows a top view of pixels for an electroluminescence (EL) display panel to be manufactured by using the reverse stagger-type TFT 751. In a pixel portion which displays an image or like of the electroluminescence display panel, an EL element, and a first TFT 9001 and a second TFT 9002 which control luminescence thereof are provided in each of pixels which constitute the pixel portion. These TFT can each be formed by using the reverse stagger-type TFT as described in Example 1. A passivation film 9010 is formed on the first TFT 9001 and the second TFT 9002. According to the present Example, the passivation film 9010 uses silicon nitride formed by the sputtering method. A concentration of Ar in the film is approximately in the range of from 5×10⁸ atoms/cm³ to 5×10²⁰ atoms/cm³.

The first TFT 9001 is connected to a pixel electrode 9009 and controls luminescence of the EL element formed on the pixel electrode. The second TFT 9002 controls an operation of the first TFT 9001 and, in this case, can control an on-off operation of the first TFT 9001 in accordance with signals of a scanning line 9003 which concurrently functions as a gate electrode of the second TFT 9002, and a signal line 9007. A gate electrode 9004 of the first TFT 9001 is connected to the second TFT 9002 and supplies power from a power supply line 9008 to a side of a pixel electrode 9009 in accordance with on-off of the gate electrode. In order to correspond to an operation of the EL element in which luminescent brightness changes in accordance with flowing current volumes, a channel width of the first TFT against a channel length is set to be in the range of from 5 times to 100 times and preferably in the range of from 10 times to 50 times. Further, the second TFT 9002 has a multi-gate structure for the purpose of reducing an off-leak current against a switching operation.

The EL element has a structure in which a layer comprising an organic compound which gives off luminescence (fluorescence) when a singlet excited state is back to a ground state thereof or/and gives off luminescence (phosphorescence) when a triplet excited state is back to a ground state thereof (hereinafter, referred to as “EL layer”) is sandwiched between by a pair of electrodes (anode and cathode). As for the organic compound which forms the EL layer, a low molecular-type organic luminescent substance, an intermediate molecular-type organic substance (organic luminescent substance having no sublimation property, a number of molecules of 20 or less or having a chained molecule length of 10 μm or less) or a high molecular-type luminescent substance can be used. The EL layer may be formed by a mono-layer or laminating a plurality of layers which have respective different functions with one another. When the plurality of layers are laminated with one another, a hole injecting-transporting layer, a light-emitting layer, an electron injecting-transporting layer, a hole or electron block layer and the like may appropriately be combined thereamong. Further, the hole injecting-transporting layer, being capable of injecting a hole from an electrode, is made of a material having a high hole mobility and two functions therein may be separated from one the other. Further, same can be said with the electron injecting-transporting layer.

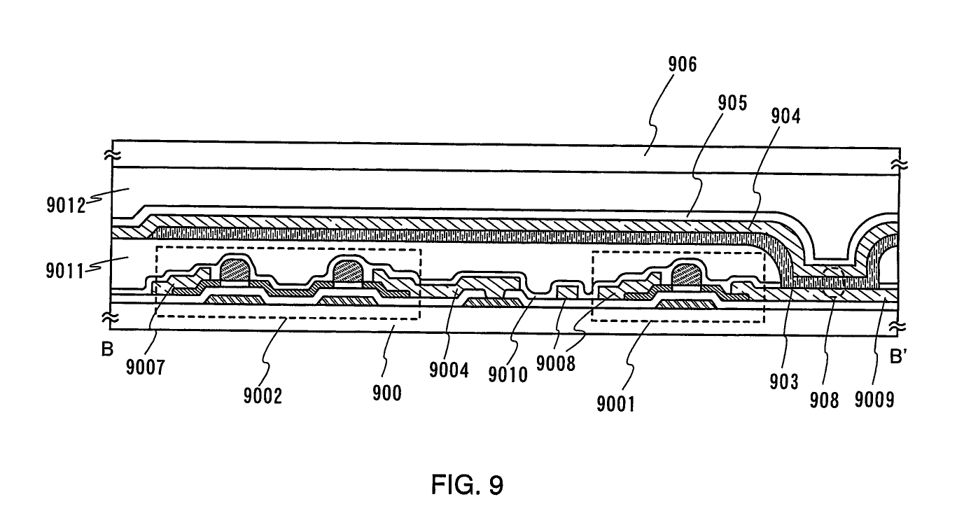

FIG. 9 is a cross-sectional diagram corresponding to FIG. 11 and shows an active matrix-type EL display panel in which an EL element 908 is formed between one substrate 900 over which a first TFT 9001, a second TFT 9002 and the like are formed, and a sealing substrate 906. A pixel electrode 9009 is provided such that it is connected to the first TFT 9001 and, then, an insulating material 9011 is formed. An EL element 908 comprising an EL layer 903 and an opposing electrode 904 are formed thereover. A passivation layer 905 is formed on the EL element 908 and is sealed by a sealing substrate 906 and a sealing material. An insulating material 9012 is filled between the passivation layer 905 and the sealing substrate 906.

As for the insulating materials 9011 and 9012, a film comprising at least one material selected from among silicon nitride, silicon oxide, silicon nitride oxide, aluminum nitride, aluminum oxide nitride, aluminum nitride oxide, aluminum oxide, diamond-like carbon (DLC), a nitrogen-containing carbon film (CN) can be used.

As for other insulating materials, a film comprising at least one material selected from among polyimide, acryl, benzocyclobutene and polyamide may be used. Further, a material containing a skeleton structure which is constructed by allowing silicon (Si) and oxygen (O) to bond with each other and at least hydrogen in a substituent or a material containing at least one member selected from among fluorine, an alkyl group and an aromatic hydrocarbon in a substituent (siloxane-type polymer as a representative example) may be used. When light is drawn out from the side of the sealing substrate 906, it is necessary to use a material having a light transmission property in the insulating material 9012.

Further, although FIGS. 9 and 11 each show only one pixel, it is permissible to allow a multi-color display by combining pixels provided with respective EL elements corresponding to colors of R (red), G (green) and B (blue). Still further, light-emission may be luminescence (fluorescence) which is given off when a singlet excited state is back to a ground state thereof in all cases, luminescence (phosphorescence) which is given off when a triplet excited state is back to a ground state thereof in all cases, or a combination of, for example, one color of fluorescence (or phosphorescence) and other two colors of phosphorescence (or fluorescence). In another case, it is permissible that only R uses phosphorescence and G and B use fluorescence. For example, a laminate structure is formed such that a copper phthalocyanine (CuPc) film having a thickness of 20 nm is provided as a hole injecting layer and, then, on the hole injecting layer, a tris-8-quinolinolato aluminum complex (Alq₃) film having a thickness of 70 nm is provided as a light-emitting layer. A light-emitting color can be controlled by adding a fluorescence dye such as quinacridone, perylene or DCM1 to Alq₃.

The passivation film 905 can be formed by using an insulating substance such as silicon nitride, silicon oxide, silicon oxide nitride, aluminum nitride, aluminum oxide nitride, aluminum oxide, diamond-like carbon or a nitrogen-containing carbon. Further, a material containing a skeleton structure which is constructed by allowing silicon (Si) and oxygen (O) to bond with each other and at least hydrogen in a substituent or a material containing at least one member selected from among fluorine, an alkyl group and an aromatic hydrocarbon in a substituent (siloxane-type polymer as a representative example) may be used.

The present invention can be applied not only to a both face emitting-type (dual emission type) luminescence display panel in which light goes outside from both faces of the luminescence display panel, but also to a single face emitting-type luminescence display panel. When light goes outside only from the side of the opposing electrode, the pixel electrode, corresponding to an anode, is a metallic layer having a reflecting property and, as for the metallic layer having a reflecting property, in order to allow it to function as an anode, a layer of metal such as platinum (Pt) or gold (Au) which has a high work function is used. Further, since these metals are expensive, a pixel electrode may be formed by laminating these metals on an appropriate metallic film such as an aluminum film or a tungsten film while allowing platinum or gold to be exposed on at least an outermost surface thereof. Still further, the opposing electrode is a metallic film having a small thickness (preferably in the range of from 10 nm to 50 nm) and, in order to allow it to function as a cathode, uses a material comprising an element belonging to Group 1 or 2 of the periodic table which has a small work function as a metallic film (for example, Al, Ag, Li, Ca, or alloys thereof such as MgAg, MgIn, AlLi, CaF₂ and CaN). Furthermore, an electrically conductive film of an oxide (ITO film as a representative example) is provided on the opposing electrode in a laminating manner. On this occasion, light emitted from the light-emitting element is reflected on the pixel electrode, passes through the opposing electrode and goes outside from the side of the sealing substrate 906.

When light goes outside only from the side of the pixel electrode, a transparent electrically conductive film is used in the pixel electrode which corresponds to the anode. As for the transparent electrically conductive film, a compound comprising indium oxide and tin oxide, a compound comprising indium oxide and zinc oxide, zinc oxide, tin oxide or indium oxide can be used. Further, the opposing electrode preferably uses a metallic film (in a thickness in the range of from 50 nm to 200 nm) comprising Al, Ag, Li, Ca, and alloys thereof such as MgAg, MgIn and AlLi. On this occasion, light emitted from the light-emitting element passes through the pixel electrode and, then, goes outside from the side of the substrate 900.

In a case both face emitting-type (dual emission type) luminescence in which light goes outside from both sides of the pixel electrode and the opposing electrode, a transparent electrically conductive film is used in the pixel electrode which corresponds to the anode. As for the transparent electrically conductive film, a compound comprising indium oxide and tin oxide, a compound comprising indium oxide and zinc oxide, zinc oxide, tin oxide or indium oxide can be used. Further, the opposing electrode is a metallic film having a small thickness (preferably in the range of from 10 nm to 50 nm) such that light can pass therethrough and, in order to allow it to function as a cathode, uses a material comprising an element belonging to Group 1 or 2 of the periodic table which has a small work function as a metallic film (for example, Al, Ag, Li, Ca, or alloys thereof such as MgAg, MgIn, AlLi, CaF₂ and CaN). Furthermore, a transparent electrically conductive film of an oxide (ITO film as a representative example) is provided on the opposing electrode in a laminating manner. On this occasion, light emitted from the light-emitting element goes outside from the both sides of the substrate 900 and the sealing substrate 906.

In the EL display panel as has been described above, since the TFT can be manufactured by using the droplet discharging method, a substantial reduction of the number of steps of the manufacturing process and the manufacturing cost can be aimed at. Further, in the present Example, described is an example in which the liquid crystal display panel is constituted by using the reverse stagger-type TFT as described in Example 1; however, the panel can also be similarly manufactured by using the positive stagger-type TFT as described in Example 2.

### Example 5

In the present Example, a state in which the liquid crystal display panel as described in Example 3 or the EL display panel as described in Example 4 is fabricated into a module is explained with reference to FIG. 8.

A module as shown in FIG. 8, driver ICs in which a driver circuit is formed are mounted around a pixel portion 701 by a COG (chip on glass) method. It goes without saying that the driver ICs may be mounted by a TAB (tape automated bonding) method.

A substrate 700 is fixed by an opposing substrate 703 and a sealing material 702. The pixel portion 701 may be such article as making use of the liquid crystal as described in Example 3 as a display medium or the EL element as described in Example 4 as a display medium. Driver ICs 705a and 705b, and other driver ICs 707a, 707b and 707c may each be an integrated circuit which is formed by using a mono-crystal semiconductor, or an equivalent one which is formed by using the TFT which is manufactured by using a poly-crystal semiconductor. A signal or power is supplied to the driver ICs 705a and 705b, and other driver ICs 707a, 707b and 707c via FPCs 706a and 706b, and FPCs 704a, 704b and 704c, respectively.

### Example 6

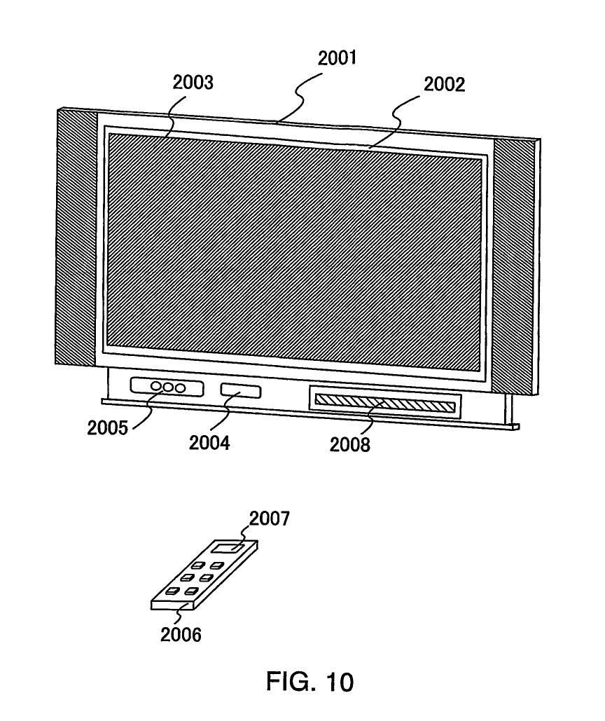

As an example of electronic apparatuses using the module as described in Example 5, a TV set as shown in FIG. 10 can be completed.

In the TV set, a display module 2002 manufactured by making use of a liquid crystal or an EL element is incorporated in a housing 2001 thereof and, then, not only an ordinary TV broadcasting can be received by a receiver 2005, but also it becomes possible to conduct a one-way information communication (from transmitter to receiver) or a two-way information communication (from transmitter to receiver or between receivers) by connecting to the telecommunication network due to a cable or radio via modem 2004. The TV set can be operated by a switch incorporated in the housing or a remote control unit 2006 separately provided and a display portion 2007 to show information to be outputted may be provided in the remote control unit.

Further, also in the TV set, in addition to a main screen 2003, an auxiliary screen 2008 is formed by a second display module and, then, a constitution which displays channels or sound volumes may be provided. In such constitution as described above, the main screen 2003 is formed by an EL display module having an excellent viewing angle and an auxiliary screen 2008 may be formed by a liquid crystal module capable of displaying at a low power consumption. Further, in order to put a priority on the low power consumption, a configuration may be constructed such that the main screen 2003 is formed by a liquid crystal display module, the auxiliary screen 2008 is formed by an EL display module and, then, the auxiliary screen can be turned on and off.

In any case, according to the present invention, since the number of steps of the manufacturing process is reduced to a great extent, the TV set having a large screen can be manufactured at lower cost. As a result, not only a low-cost TV set can be supplied, but also such new function as described above is added and, accordingly, convenience of the TV set can be enhanced.

### Example 7

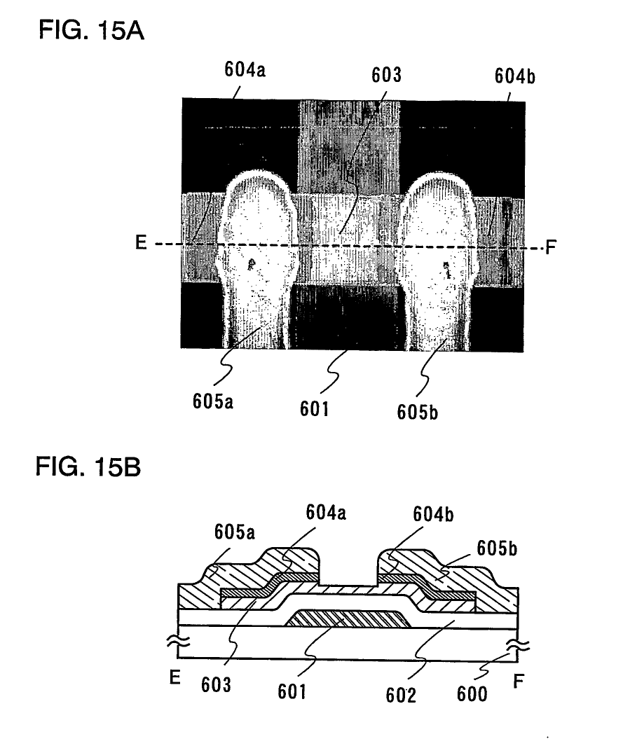

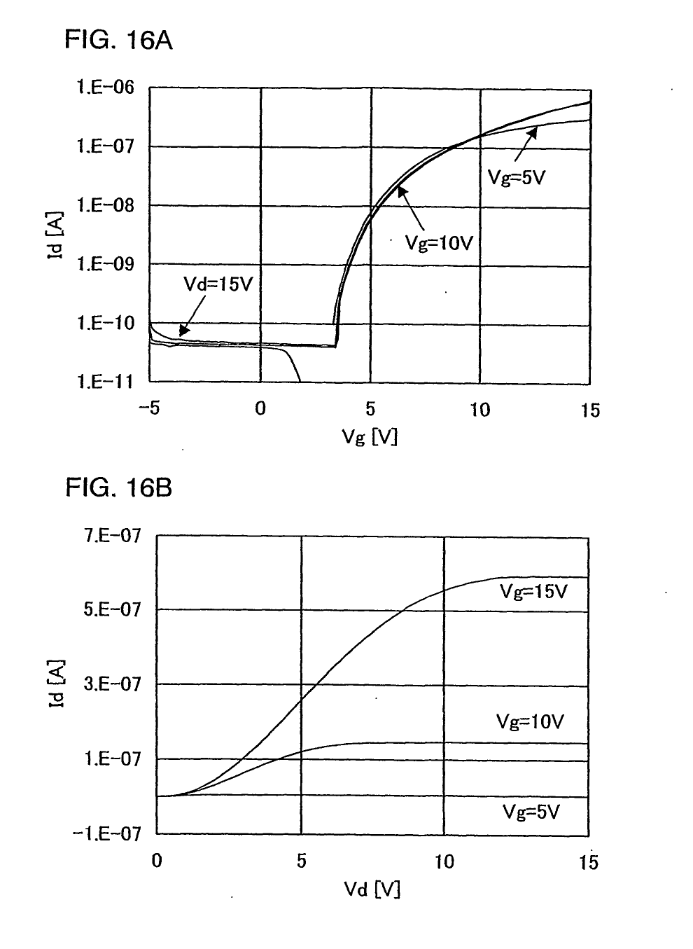

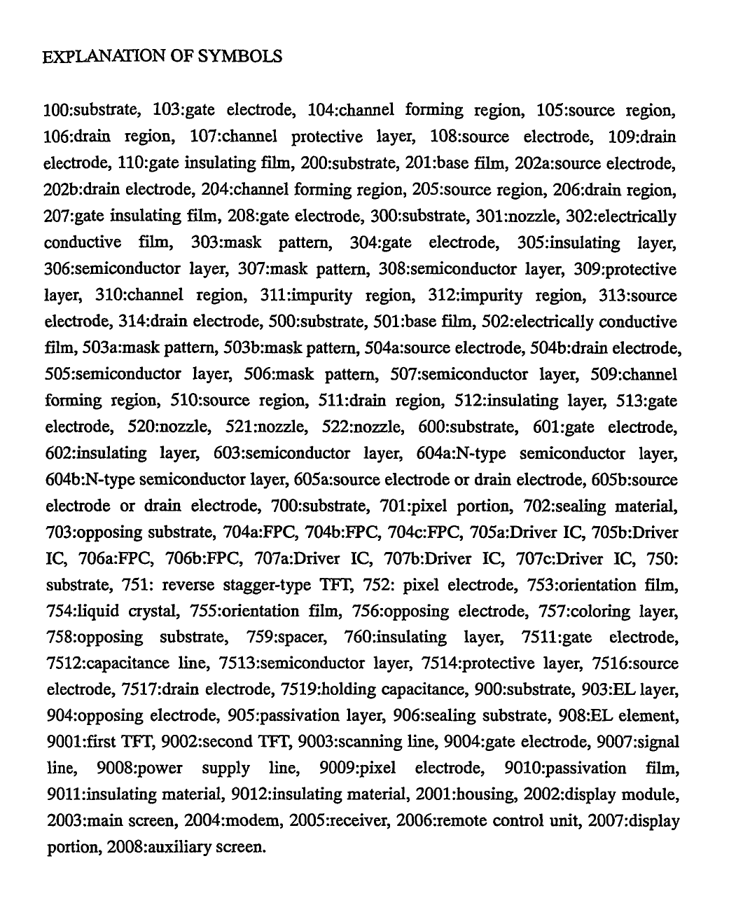

Another example of a thin film transistor to which the present invention is applied is explained with reference to FIGS. 15 and 16.

The thin film transistor according to the present Example is a bottom gate-type thin film transistor using an amorphous semiconductor layer. FIG. 15A is an optical micrograph showing a top view of the manufactured thin film transistor and FIG. 15B shows a cross-sectional diagram taken along the line E-F of FIG. 15A. An electrically conductive film was formed on a substrate 600 and, then, the electrically conductive film was subjected to patterning by using a mask pattern, to thereby form a gate electrode 601. On this occasion, the electrically conductive film was a tungsten film formed by a sputtering method while the mask pattern was manufactured by selectively discharging a composition comprising polyimide by a droplet discharging method.

On the gate electrode 601, an insulating layer 602 was formed. As for the insulating layer 602, a silicon oxynitride film formed by a CVD method was used. On the insulating layer 602, N-type semiconductor layers were formed as a semiconductor layer as well as one conductivity type (p-type or n-type) semiconductor layer and, then, they were subjected to patterning, to thereby form a semiconductor layer 603, an N-type semiconductor layer 604a and an N-type semiconductor layer 604b. Mask patterns for the semiconductor layer and the N-type semiconductor layer were manufactured by selectively discharging a composition comprising polyimide by means of the droplet discharging method in a same manner as in the mask pattern of the gate electrode.

On the insulating layer 602, semiconductor layer 603, N-type semiconductor layer 604a and N-type semiconductor layer 604b, a source electrode or drain electrode 605a, and a source electrode or drain electrode 605b were formed by discharging a composition comprising Ag as an electrically conductive material by means of the droplet discharging method. In such manner as described above, the thin film transistor to which the present invention was applied was manufactured.

In the thin film transistor manufactured in the present Example, the N-type semiconductor layer 604a and N-type semiconductor layer 604b, the source electrode or drain electrode 605a, and the source electrode or drain electrode 605b overlap the gate electrode 601.

Electric characteristics of the thin film transistor as thus manufactured above are shown in FIGS. 16A and 16B. FIG. 16A shows gate voltage (Vg)-drain current (Id) characteristics at the time the drain voltages (Vd) are 5V, 10V and 15V. FIG. 16B shows drain voltage (Vd)-drain current (Id) characteristics at the time the gate voltages (Vg) are 5V, 10V and 15V. An off-current was 1×10⁻¹⁰ or less and, accordingly, relatively favorable TFT characteristics were obtained. An electric field effect mobility thereof (μ) was 0.2 cm²/Vsec, and a threshold voltage was 3.97 V.

According to the present invention, by forming a mask pattern by the droplet discharging method, steps of, for example, applying a resist, baking the resist, exposing, developing and baking after such development can be omitted. As a result, a substantial reduction of cost due to simplification of the steps can be aimed.

Further, since an electrically conductive layer or the like can be formed in a desired pattern in an arbitrary place and, also, thickness or width of the electrically conductive layer to be formed can be adjusted, a manufacturing can be executed on a large area substrate having a side of more than 1 meter at lower cost and, also, at higher yield.

1. A thin film transistor comprising:
a gate electrode;
a semiconductor including a source region, a drain region and a channel forming region formed over the gate electrode; and
a protective layer comprising an organic resin,
wherein the protective layer is formed at a position at which the channel forming region exists on a surface of the semiconductor film opposite to the gate electrode.

2. A thin film transistor comprising:
a gate electrode;
a semiconductor including a source region, a drain region and a channel forming region formed over the gate electrode; and
a protective layer comprising an organic resin,
wherein the protective layer is selectively formed over the channel forming region.

3. A thin film transistor comprising:
a gate electrode;
a semiconductor including a source region, a drain region and a channel forming region formed over the gate electrode; and
a protective layer comprising an organic resin,
wherein the protective layer is formed in contact with at least the channel forming region.

4. A thin film transistor according to claim 1, wherein the semiconductor is an amorphous semiconductor or a semi-amorphous semiconductor.

5. A thin film transistor according to claim 2, wherein the semiconductor is an amorphous semiconductor or a semi-amorphous semiconductor.

6. A thin film transistor according to claim 3, wherein the semiconductor is an amorphous semiconductor or a semi-amorphous semiconductor.

7. A thin film transistor according to claim 1, wherein the organic resin comprises at least one selected from among polyimide, acryl, benzocyclobutene, and polyamide.

8. A thin film transistor according to claim 2, wherein the organic resin comprises at least one selected from among polyimide, acryl, benzocyclobutene, and polyamide.

9. A thin film transistor according to claim 3, wherein the organic resin comprises at least one selected from among polyimide, acryl, benzocyclobutene, and polyamide.

10. A thin film transistor according to claim 1, wherein the source region and the drain region are an impurity region having an impurity which imparts an n-type.

11. A thin film transistor according to claim 2, wherein the source region and the drain region are an impurity region having an impurity which imparts an n-type.

12. A thin film transistor according to claim 3, wherein the source region and the drain region are an impurity region having an impurity which imparts an n-type.

13. A manufacturing method of a thin film transistor comprising the steps of:
forming a first electric conductor;
forming a first insulator and a semiconductor over the first electric conductor in a laminating manner;
forming a first pattern on the semiconductor;
subjecting the semiconductor to patterning by using the first pattern;
forming a second pattern on the patterned semiconductor,
forming an impurity region by incorporating an impurity into the semiconductor by making use of the second pattern as a mask; and
forming a second electric conductor in contact with the impurity region,
wherein the first and second patterns are each formed by selectively discharging a composition comprising an organic resin, and
wherein the first and second electric conductors are each formed by selectively discharging a composition comprising an electrically conductive material.

14. A manufacturing method of a thin film transistor comprising the steps of:
forming a first electric conductor;
forming a first pattern on the first electric conductor;
subjecting the first electric conductor to patterning by making use of the first pattern;
forming a first insulator and a semiconductor over the patterned first electric conductor in a laminating manner;
forming a second pattern on the semiconductor;
subjecting the semiconductor to pattering by making use of the second pattern;
forming a third pattern on the patterned semiconductor;
forming an impurity region by incorporating an impurity into the semiconductor by making use of the third pattern as a mask; and
forming a second electric conductor on the impurity region,
wherein the first to third patterns are each formed by selectively discharging a composition comprising an organic resin, and
wherein the second electric conductor is formed by selectively discharging a composition comprising an electrically conductive material.

15. A manufacturing method of a thin film transistor comprising the steps of:
forming a first electric conductor;
forming a first pattern on the fist electric conductor;
subjecting the first electric conductor to patterning by making use of the first pattern;
forming a first insulator and a semiconductor over the patterned first electric conductor in a laminating manner;
forming a second pattern on the semiconductor;
subjecting the semiconductor to pattering by making use of the second pattern;
forming a third pattern on the patterned semiconductor;
forming an impurity region by incorporating an impurity into the semiconductor by making use of the third pattern as a mask; and
forming a second electric conductor on the impurity region;
forming a fourth pattern on the second electric conductor; and
subjecting the second electric conductor to pattering by making use of the fourth pattern,
wherein the first to fourth patterns are each formed by selectively discharging a composition comprising an organic resin.

16. A manufacturing method of the thin film transistor according to claim 13, wherein the semiconductor is an amorphous semiconductor or a semi-amorphous semiconductor.

17. A manufacturing method of the thin film transistor according to claim 14, wherein said semiconductor is an amorphous semiconductor or a semi-amorphous semiconductor.

18. A manufacturing method of the thin film transistor according to claim 15, wherein said semiconductor is an amorphous semiconductor or a semi-amorphous semiconductor.

19. A manufacturing method of the thin film transistor according to claim 13, wherein said electrically conductive material comprises at least one material selected from among silver, gold, copper and indium tin oxide.

20. A manufacturing method of the thin film transistor according to claim 14, wherein said electrically conductive material comprises at least one material selected from among silver, gold, copper and indium tin oxide.

21. A manufacturing method of the thin film transistor according to claim 13, wherein said pattern comprises at least one material selected from among polyimide, acryl, benzocyclobutene, and polyamide.

22. A manufacturing method of the thin film transistor according to claim 14, wherein said pattern comprises at least one material selected from among polyimide, acryl, benzocyclobutene, and polyamide.

23. A manufacturing method of the thin film transistor according to claim 15, wherein said pattern comprises at least one material selected from among polyimide, acryl, benzocyclobutene, and polyamide.

24. A manufacturing method of the thin film transistor according to claim 13, further comprising the steps of incorporating an impurity which imparts an n-type.

25. A manufacturing method of the thin film transistor according to claim 14, further comprising the steps of incorporating an impurity which imparts an n-type.

26. A manufacturing method of the thin film transistor according to claim 15, further comprising the steps of incorporating an impurity which imparts an n-type.

27. A manufacturing method for a display device comprising the steps of:
forming a pixel region in which a plurality of first semiconductor elements are arranged over a first substrate;
forming a liquid crystal element between the first substrate and a second substrate;
forming a plurality of driver ICs which each contains a driver circuit in which a plurality of second semiconductor elements are arranged, and each contains an input terminal and an output terminal connected to the driver circuit over a third substrate;
separating the plurality of driver ICs into individual driver ICs;
attaching the driver ICs over the first substrate each as a signal line driver circuit or a scanning line driver circuit,
forming a pattern which subjects a semiconductor constituting the first semiconductor element to patterning by selectively discharging a composition comprising an organic resin; and
forming a channel protective layer of the first semiconductor element by selectively discharging a composition comprising an organic resin.

28. A manufacturing method for a display device comprising the steps of:
forming a pixel region in which a plurality of first semiconductor elements are arranged over a first substrate;
forming a light-emitting element between the first substrate and a second substrate;
forming a plurality of driver ICs which each contains a driver circuit in which a plurality of second semiconductor elements are arranged, and each contains an input terminal and an output terminal connected to the driver circuit over a third substrate;
separating the plurality of driver ICs into individual driver ICs;
attaching the driver ICs over the first substrate each as a signal line driver circuit or a scanning line driver circuit,
forming a pattern which subjects a semiconductor constituting the first semiconductor element to patterning by selectively discharging a composition comprising an organic resin; and
forming a channel protective layer of the first semiconductor element by selectively discharging a composition comprising an organic resin.

29. A manufacturing method for the display device according to claim 27, further comprising the steps of forming an amorphous semiconductor or a semi-amorphous semiconductor as a channel region of the first semiconductor element.

30. A manufacturing method for the display device according to claim 28, further comprising the steps of forming an amorphous semiconductor or a semi-amorphous semiconductor as a channel region of the first semiconductor element.

31. A manufacturing method for the display device according claim 27, further comprising the steps of forming an impurity region by incorporating an impurity into the first semiconductor element by making use of the channel protective layer as a mask.

32. A manufacturing method for the display device according claim 28, further comprising the steps of forming an impurity region by incorporating an impurity into the first semiconductor element by making use of the channel protective layer as a mask.

33. A manufacturing method for a display device according to claim 27,
wherein the first semiconductor element further comprises an electric conductor, and
wherein said electric conductor is formed by selectively discharging a composition comprising an electrically conductive material.

34. A manufacturing method for the display device according to claim 28,
wherein the first semiconductor element further comprises an electric conductor, and
wherein said electric conductor is formed by selectively discharging a composition comprising an electrically conductive material.

35. A manufacturing method for the display device according to claim 27,
wherein the first semiconductor element further comprises an electric conductor, and
wherein a pattern which subjects the electric conductor to patterning by selectively discharging a composition comprising an organic resin.

36. A manufacturing method for the display device according to claim 28,
wherein the first semiconductor element further comprises an electric conductor, and
wherein a pattern which subjects the electric conductor to patterning by selectively discharging a composition comprising an organic resin.

37. A manufacturing method for the display device according to claim 33, wherein the electrically conductive material comprises at least one material selected from among silver, gold, copper and indium tin oxide.

38. A manufacturing method for the display device according to claim 34, wherein the electrically conductive material comprises at least one material selected from among silver, gold, copper and indium tin oxide.

39. A manufacturing method for the display device according to claim 27, wherein the channel protective layer comprises at least one material selected from among polyimide, acryl, benzocyclobutene, and polyamide.

40. A manufacturing method for the display device according to claim 28, wherein the channel protective layer comprises at least one material selected from among polyimide, acryl, benzocyclobutene, and polyamide.

41. A manufacturing method for the display device according to claim 27, wherein the pattern comprises at least one material selected from among polyimide, acryl, benzocyclobutene, and polyamide.

42. A manufacturing method for the display device according to claim 28, wherein the pattern comprises at least one material selected from among polyimide, acryl, benzocyclobutene, and polyamide.

43. A manufacturing method for the display device according to claim 27, further comprising the steps of incorporating an impurity which imparts an n-type into the first semiconductor element by making use of the channel protective layer as a mask, and forming a channel region.

44. A manufacturing method for the display device according to claim 28, further comprising the steps of incorporating an impurity which imparts an n-type into the first semiconductor element by making use of the channel protective layer as a mask, and forming a channel region.

45. A manufacturing method for the display device according to claim 27, wherein the channel forming region of a semiconductor of the second semiconductor element is formed by polycrystal silicon.

46. A manufacturing method for a display device according to claim 28, wherein the channel forming region of a semiconductor of the second semiconductor element is formed by polycrystal silicon.
